(19) United States
(12) Patent Application Publication
(10) Pub. No.: US 2015/0090030 A1
(43) Pub. Date: Apr. 2, 2015

(54) Transducer arrangement comprising a transducer die and method of covering a transducer die

(71) Applicant: Infineon Technologies AG, Neubiberg (DE)

(72) Inventor: Horst THEUSS, Wenzenbach (DE)

(73) Assignee: Infineon Technologies AG, Neubiberg (DE)

(21) Appl. No.: 14/039,365

(22) Filed: Sep. 27, 2013

(51) Int. Cl. G01D 11/24; H01L 21/52

(52) U.S. Cl. CPC G01D 11/245; H01L 21/52
USPC 73/431; 438/106

(57) ABSTRACT

According to an exemplary aspect a transducer arrangement comprising a supporting structure; a transducer die arranged on the supporting structure; and a lid comprising a porous material connected to the supporting structure and arranged to at least partially cover the transducer die.

### BACKGROUND OF THE INVENTION

1. Field of the Invention

The present invention relates to transducer arrangement comprising a transducer die. Moreover, the present invention relates to a method of covering a transducer die.

2. Description of the Related Art

In the art a plurality of electronic modules are known which comprises an electronic or semiconductor chip providing some electronic functionality. The electronic chip may be arranged or placed on a substrate and may be packaged in order to provide some protection function for the electronic chip.

In particular, the electronic chip may form or may be part of a sensor, like a pressure sensor, a microphone or a gas sensor. While such sensors are preferably protected from the environment, for example from particles and or chemical influence, e.g. corrosion, these kinds of sensors need to be in direct contact to the environment, e.g. a pressure change has to be detected by the active component of the sensor or a specific gas to be detected has to be able to reach the active component. Thus, the package should not hermetically sealing off the active component but allow for at least a partial interaction with the environment.

One possibility to protect a pressure sensor, which is known in the art (e.g. US 2006053895 A1), is schematically shown in FIG. 5.

In particular, FIG. 5 shows a sensor arrangement 500 with a cavity 501 comprising a cavity housing 502, e.g. formed by a molded plastic material, laminated structure of PCB-multilayers or ceramic, or formed by any other suitable material or method, and further comprising a leadframe 503, e.g. a leadless or bent leadframe.

In the cavity 501 a sensor die 504, e.g. a pressure sensor, is attached to a bottom of the cavity by an adhesive material 505 for example. The sensor die 504 is furthermore electrically connected via bonding wires 506 to an exterior of the sensor arrangement, e.g. via the leadfame, by connecting bonding or contact pads 507 to the leadframe 503. The sensor die or chip 504 comprises an active area 508, which may be formed by a membrane in case of a pressure sensor. For protecting the sensor die 504 a gel material 509 is used to cover the active sensor die 504 by filling the cavity 501. Alternatively the cavity 501 may be covered by a lid or cover which comprises a hole in order to, on the one hand, provide a covering or protection for the sensor die while on the other hand to enable that the sensor die is not totally shielded off from the environment.

### SUMMARY OF THE INVENTION

In general, there may be a need to provide a transducer arrangement and a method of manufacturing the same wherein the transducer arrangement provides for a good particle protection of a transducer die of the transducer arrangement.

According to an exemplary aspect a transducer arrangement is provided which comprises a supporting structure, a transducer die arranged on the supporting structure, and a lid comprising a porous material connected to the supporting structure and arranged to at least partially cover the transducer die.

According to an exemplary aspect a method of covering a transducer die of a transducer arrangement is provided, wherein the method comprises providing a supporting structure; arranging the transducer die on the supporting structure; and at least partially covering the arranged transducer die by placing a lid comprising a porous material on the supporting structure.

According to an exemplary aspect a transducer arrangement is provided which comprises a supporting structure; a transducer die arranged on the supporting structure; a lid comprising a material which comprises a plurality of through holes, wherein the lid is connected to the supporting structure and arranged to at least partially cover the transducer die.

The provision of a lid comprising porous material or a material having a plurality of through holes may allow for a good particles protection of the transducer die. At the same time the lid may allow for a simple handling and arranging of the lid on the transducer arrangement or supporting structure during the manufacturing of the transducer arrangement. Furthermore, the porous material may be selected to have a high chemical resistance and provide a high corrosion resistance. Thus, the provision of the porous material may be beneficial when compared to the use of a single gel compound since the chemical and/or mechanical durability may be increased. Additionally, a porous lid may enable a wide range of applications.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 shows a schematic cross sectional view of a transducer arrangement according to an exemplary embodiment;

FIG. 2 shows a schematic cross sectional view of a transducer arrangement according to another exemplary embodiment;

FIG. 3A shows a schematic cross sectional view of a transducer arrangement according to another exemplary embodiment;

FIG. 3B shows the transducer arrangement of FIG. 3A having a lid arranged on the transducer arrangement;

FIG. 4 schematically shows steps of a process of covering a transducer die of a transducer arrangement according to an exemplary embodiment;

FIG. 5 shows a schematic cross sectional view of a sensor arrangement.

### DESCRIPTION OF FURTHER EXEMPLARY EMBODIMENTS

In the following, further exemplary embodiments of the transducer arrangement and the method of manufacturing the same will be explained. It should be noted that embodiments described in the context of the transducer arrangement may also be combined with embodiments of the method of manufacturing the transducer arrangement and vice versa.

In particular, the transducer die may be a semiconductor die, e.g. an integrated semiconductor die, and/or may form an integrated transducer. In particular, the transducer die may be a sensor die. Exemplary dimensions of the transducer die may be in the range of 2.5 cm×2.5 cm, more particularly in the range of 1.5 cm×1.5 cm, preferably in the range of 0.7 cm×0.7 cm to 0.5 mm×0.5 mm. Furthermore, the lid may have a thickness which is selected based on the application the transducer arrangement is used for. For example, based on a necessary protection to be provided for the transducer die the thickness and/or the porosity of the lid may be chosen or selected. In particular, the handling of the lid and/or of the transducer arrangement may be performed with common pick and place tools. Possible applications may be barometric pressure sensor technology, impact sensor technology (as used in airbag technology); in particular pressure sensor technology used in environments imposing restrictions with respect to chemical and/or thermal durability, e.g. in the automotive technology, like manifold air pressure applications, power train applications, e.g. exhaust gas recirculation.

The term “porous material” may particularly denote a material through which a fluid compound may pass, e.g. which comprises open pores connected with each other. In particular, a porous material may have a porosity which is above a predetermined threshold.

The use of a lid comprising or consisting of a porous material may enable a good protection of the transducer die arranged in the cavity while still enable a material transport through the lid to the transducer die. In particular, the porous lid may protect the transducer die from particles.

According to an exemplary embodiment of the transducer arrangement the porous material is selected out of the group consisting of porous polyethylene; porous polypropylene; porous polytetrafluoroethylene; porous polyvinylidene fluoride; porous ethyl-vinyl acetate; porous polycarbonate; porous polyamide; porous thermoplastic polyester polyurethane; porous polyethersulfone; and porous metal.

In particular, the porous metal may be aluminium (anodized if necessary), copper, zinc, lead or iron. The different porous materials may be chosen depending on the application. For example, polyethylene is a strong and lightweight material which is resistant against concentrated acids, bases and many organic solvents; polypropylene is elastic, resistant against most acids and bases; polytetrafluoroethylene is rather inert, has a high tensile strength, and has a high temperature resistance; polyvinylidene is a hard, low weight material having a high abrasion resistance, is UV resistant and withstands high thermal and chemical stress; and ethyl-vinyl acetate is highly elastic but robust.

According to an exemplary embodiment of the transducer arrangement the porous material is a material with a porosity of at least 0.05.

That is, a given or predetermined threshold for the porosity of the porous material of the lid may be at least 0.05. In particular, the porosity may be at least 0.1 or 0.25, preferably at least 0.5 and more preferably at least 0.75. The porosity may be chosen or selected depending on the needs of the used transducer die and/or the intended application, for example. In particular, each specific kind of transducer die may advantageously be combined with a porous lid with a different porosity in order to provide a sufficient level of operation. The porosity may be defined as the ratio of void space or volume to the total space or volume of the element, i.e. including voids and solid material. In other words the term porosity is a measure of the void (i.e., “empty”) spaces in a material, and is a fraction of the volume of voids over the total volume.

According to an exemplary embodiment of the transducer arrangement the supporting structure is a structure selected out of the group consisting of: a molded structure; a lead frame; a printed circuit board; a multilayer structure; a ceramic structure; a laminated structure; and a substrate.

In particular, the substrate may be a common semiconductor substrate, i.e. a substrate commonly used in the semiconductor technology, e.g. a silicon substrate.

According to an exemplary embodiment of the transducer arrangement the supporting structure comprises an open cavity structure, wherein the transducer die is arranged in the open cavity structure.

In particular, the lid may be arranged to at least partially close the open cavity. The provision of a cavity may be an efficient way to provide space or a region for arranging the transducer die which is already greatly protected from impacting particles.

The term “cavity structure” may particularly denote a structure comprising a cavity. In particular, the cavity may be formed or may be surrounded by portions of the cavity structure. The cavity structure may be formed or may comprise any material which is suitable to form a durable cavity, e.g. may be formed by a mold structure, a multilayer structure, a ceramic structure, or a laminated structure, e.g. comprising a printed circuit board or another kind of substrate. In particular, the cavity structure may comprise a ridge portion which may form a seat adapted to accommodate the lid.

According to an exemplary embodiment of the transducer arrangement the transducer die forms one transducer out of the group consisting of a pressure sensor, a chemical sensor, a microphone, loudspeaker, and a gas sensor.

In particular, the pressure sensor may be an integrated pressure sensor, the microphone may be an integrated microphone and/or the gas sensor may be an integrated gas sensor and/or the chemical sensor may be an integrated chemical sensor and/or the loudspeaker may be an integrated loudspeaker. All these sensors or transducers are transducers which are advantageously in a fluid communication with an external volume, i.e. gas or liquid coming from an external region or space and coming in contact with the transducer itself. For these kinds of transducers a porous lid or lid comprising porous material may be specifically suitable since on the one hand the porous material protects the transducer with respect to particles while on the other hand allows for passing of gaseous or liquid components. A pressure sensor may be sensitive in the range of 0 to 10 bar (1 megapascal).

According to an exemplary embodiment of the transducer arrangement the porous lid comprises a solid edge portion.

In particular, the solid edge portion may encircle or surround a porous portion of the porous lid. In this context the term “solid edge portion” may particularly denote a portion which is solid or non-porous or at least has a porosity which is much lower than the one of the porous material. For example, the porosity of the solid edge portion may be smaller by a factor of at least two, more preferably by a factor of at least three, still more preferably by a factor of at least four and even still more preferably by a factor of five. In particular, the solid edge portion may have a predetermined extension or width which is suitable to allow for a simple connection or fixing of the porous lid to the cavity structure. Preferably, the solid edge portion may form a contact portion which contacts the cavity structure. In particular, the porous lid and the cavity structure contact or touch each other only at the solid edge portion.

According to an exemplary embodiment of the transducer arrangement the transducer die comprises contact pads adapted to provide an electrical contact between the transducer die and an environment external to the transducer arrangement.

In particular, the transducer die may be electrically connected to the contact pads by wires, bond wires or any other suitable electrically conductive elements, e.g. conductor paths.

According to an exemplary embodiment of the transducer arrangement the contact pads comprise non-corrosive electrically conductive material.

In particular, the non-corrosive electrically conductive material may be a noble metal, e.g. gold, silver or the like. Alternatively a metal may be used which, due to the formation of a passivation layer, is non-corrosive, e.g. aluminium. The use of non-corrosive material for the contact pads or further electrical conductive elements, e.g. bonding wires, or conductor paths, may provide for a chemical protection of the electrical contacts which in combination with the particles protection by the porous lid provides for an efficient protection of the transducer die and its electrical connections in the transducer arrangement.

According to an exemplary embodiment of the transducer arrangement the contact pads are covered by a protection layer.

In particular, the contact pads and further elements or structures used for electrical connecting the transducer die with contact pads or other electrical contact elements may be covered by the protection layer. For example, parylene, polyimide, mold compound or any other suitable organic and/or inorganic, e.g. silicon oxide or silicon nitride, materials may be used for the passivation layer. However, preferably an active area of the transducer die, e.g. a membrane, is kept free of the protection layer so that a sensitivity of the transducer die or transducer is in general not reduced. That is, the active area of the transducer die may be protection layer free. In case the active area of the transducer die is kept free of the protection layer the protection layer may be formed in a robust way, in particular in a more robust way than in the case the transducer die is covered by a gel component. For example, the material used for the protection layer may be chemically more robust or stable than known gel components.

According to an exemplary embodiment of the transducer arrangement the porous lid is attached to the supporting structure by at least one process out of the group of processes consisting of glueing, sintering, molding, soldering, and welding.

According to an exemplary embodiment of the transducer arrangement the transducer die is partially covered by a mold compound.

In particular, the transducer die may be molded into a mold compound, i.e. the mold compound may have direct contact with the transducer die. However, an active area or active region, e.g. a membrane of the transducer die, is preferably kept free of the mold compound, so that the active area may be still in fluid communication or fluid connection with an exterior of the transducer arrangement.

According to an exemplary embodiment of the transducer arrangement the mold compound comprises a seat adapted to accommodate the lid.

In particular, the seat may have a form or shape which matches a form or shape of the lid. For example, in case the lid has a tapered form or shape the seat may have a complementary form or shape which matches the tapered lid. Thus, an attachment of the lid may be simplified.

According to an exemplary embodiment of the transducer arrangement a gel compound is arranged on the transducer die.

The combination of a lid comprising porous material and a gel compound may particularly advantageous since the porous lid may provide a protection against particle for the transducer die and for the gel compound while the gel compound may provide a protection against corrosion or chemical degradation of the transducer die or electrical connections/pads.

According to an exemplary embodiment of the transducer arrangement a number of through holes is at least three. In particular, the number of through holes is at least ten, more particularly more than 25.

Summarizing a gist of an exemplary embodiment may be seen in providing a transducer arrangement comprising a transducer die, e.g. an integrated semiconductor transducer, which is placed or arranged on a supporting structure, like a multilayer structure or leadframe and protected from impinging or impacting particles by a porous lid arranged in such a way that the porous lid at least covers the transducer die, in particular a sensitive area of the transducer die. The provision of a porous lid or a lid comprising porous material, like metal or plastic foams may enable a simple structure for protecting the transducer die from particle and may be combined with an optional protection layer which may enable a further protection against chemical degradation of the transducer die and/or connection pads and/or connection paths used to connect the transducer die with components external to the transducer arrangement. The use of the porous lid may have the advantage that robust or stable materials may be used instead of a rather soft material, e.g. a gel material, which is commonly used as particle protection in the field of transducer arrangements.

### DETAILED DESCRIPTION OF THE FIGURES

The above and other objects, features and advantages of the present invention will become apparent from the following description and the appended claims, taken in conjunction with the accompanying drawings, in which like parts or elements are denoted by like reference numbers.

The illustration in the drawing is schematically and not necessarily to scale.

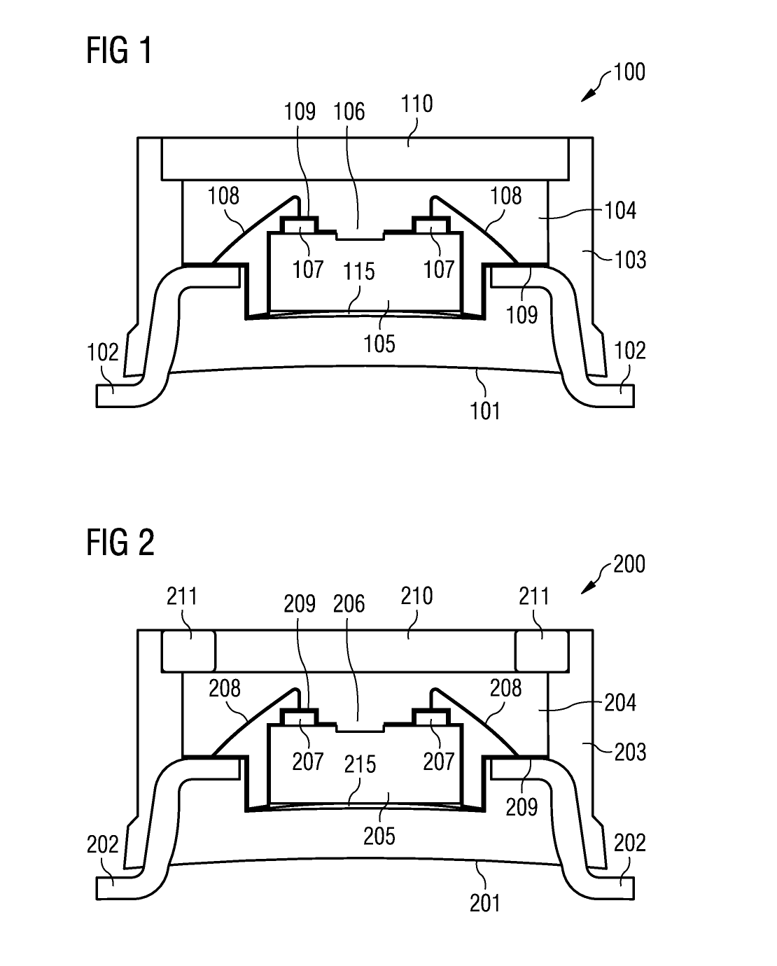

FIG. 1 shows a schematic cross sectional view of a transducer arrangement according to an exemplary embodiment. In particular, FIG. 1 shows a transducer arrangement 100 comprising a supporting structure 101 comprising a leadframe 102 on which a plastic or shapeable compound 103 is arranged so that a cavity 104 is formed. In the cavity 104 a transducer die 105 is arranged, e.g. fixed by a glue layer or solder layer 115. According to the embodiment of FIG. 1 the transducer die 105 forms a microphone and comprises a membrane 106 and contact pads 107. However, alternatively the transducer die may form a loudspeaker, gas or pressure detector. The contact pads 107 are connected to the leadframe 102 by bonding wires 108 to provide an electrical connection of the transducer die 105 to an exterior of the transducer arrangement 100. Portions of the leadframe 102 the bonding wires 108 and the contact pads 107 are covered by a protection layer 109 to provide for a corrosion protection. However, the membrane 106 is advantageously not covered by the protection layer so that the sensitivity of the membrane 106 and thus the transducer die is not reduced. Alternatively or additionally to the protection layer 107 the contact pads, bond wires and/or connection paths may be formed by non-corrosive materials, e.g. noble metals like gold or silver; and/or an additional gel compound may be used to cover the electrical connection and and/or transducer die 105.

On top of the cavity 104 and thus on top of the transducer die 105 arranged in the cavity 104 a lid 110 comprising a porous material is arranged or placed. The porous lid 110 may be glued, welded or soldered to the supporting structure 100. In particular, the supporting structure 101 may comprise a seat onto which the lid 110 may be easily placed. The porous lid 110 provides a particle protection for the transducer die 105 while still allowing fluid, i.e. gas and/or liquid, to reach the transducer die 105 or more particularly the membrane 106 of the transducer die 105.

FIG. 2 shows a schematic cross sectional view of another transducer arrangement according to an exemplary embodiment. In particular, FIG. 2 shows a transducer arrangement 200 comprising a supporting structure 201 comprising a leadframe 202 on which a plastic or shapeable compound 203 is arranged to so that a cavity 204 is formed. In the cavity 204 a transducer die 205 is arranged. According to the embodiment of FIG. 1 the transducer die 205 forms a microphone and comprises a membrane 206 and contact pads 207. However, alternatively the transducer die may form a loudspeaker, or a pressure or gas detector. The contact pads 207 are connected to the leadframe 202 by bonding wires 208 to provide an electrical connection of the transducer die 205 to an exterior of the transducer arrangement 200. Portions of the leadframe 202 the bonding wires 208 and the contact pads 207 are covered by a protection layer 209 to provide for a corrosion protection. However, the membrane 206 is advantageously not covered by the protection layer so that the sensitivity of the membrane 206 and thus the transducer die is not reduced.

On top of the cavity 204 and thus on top of the transducer die 205 arranged in the cavity 204 a lid 210 comprising a porous material is arranged or placed. Contrary to the lid 110 of the embodiment of FIG. 1 the lid 210 of the embodiment of FIG. 2 comprises a solid edge portion 211 which may simplify the attachment of the lid 210 to the supporting structure 201. The porous lid 210 provides a particle protection for the transducer die 205 while still allowing fluid, i.e. gas and/or liquid, to reach the transducer die 205 or more particularly the membrane 206 of the transducer die 205.

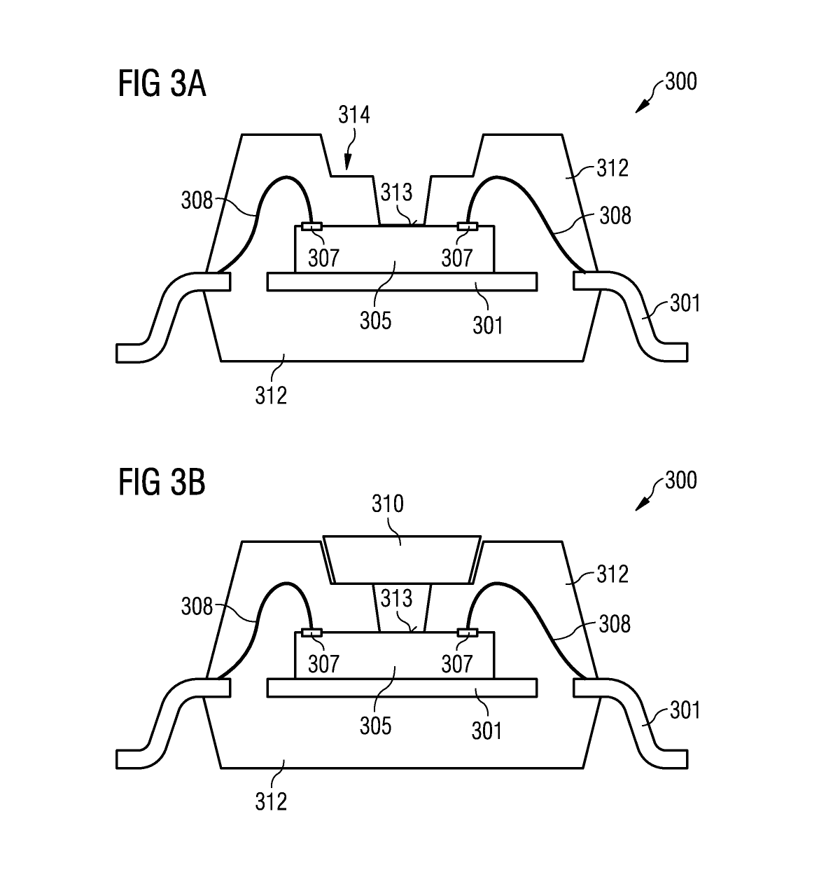

FIG. 3A shows a schematic cross sectional view of a transducer arrangement according to another exemplary embodiment. In particular, FIG. 3A shows a transducer arrangement 300 comprising a leadframe or board 301 on which a transducer die 305 is arranged. After the arranging the contact pads 307 of the transducer die 305 are electrically connected via bond wires 308 to the leadframe 301. After that the leadframe 301 and the transducer die 305 is encapsulated by a mold compound 312 providing a particle and chemical protection of the transducer die 305 and the electrically connecting elements, like contact pads 307 and bonding wires 308. However, an active portion 313 of the transducer die 305, e.g. a membrane, is kept free of the mold compound 312 so that gas and/or pressure can reach the active portion of the transducer die 305. The mold compound 312 comprises a seat 314 which may have a tapered form or shape and which is adapted to accommodate a lid.

FIG. 3B shows the transducer arrangement of FIG. 3A having a lid 315 comprising a porous material arranged on the transducer arrangement 300. In particular, the lid 310 generally matches the form or shape of the seat 314. The lid 310 provides for a particle protection of the active or sensitive area of the transducer die 305, while the mold compound 312 provides for a corrosion protection of the electrical connection elements of the transducer arrangement 300.

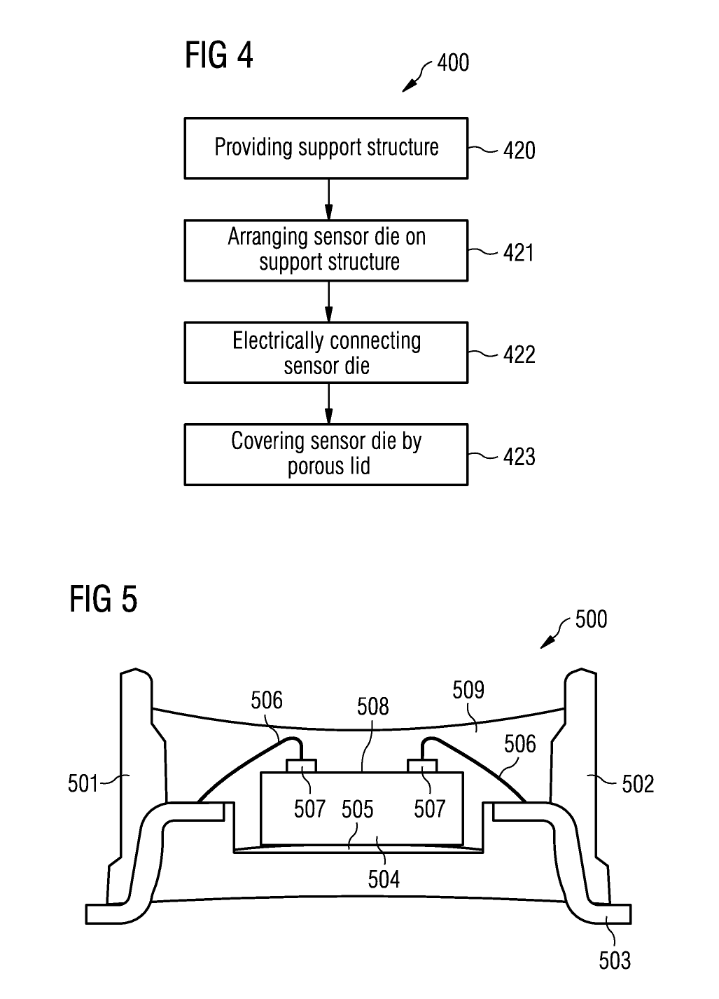

FIG. 4 schematically shows steps of a process 400 of covering a transducer die of a transducer arrangement according to an exemplary embodiment. In a first step 420 a supporting structure, e.g. a lead frame, is provided. In a later step 421 a transducer die is arranged, e.g. fixed by glue or soldered, on the supporting structure. After that the transducer die may be optionally provided with electrical connections (step 422). Then a lid comprising porous material is placed on the supporting structure, e.g. a seat formed at the supporting structure, to at least partially covering the transducer die (step 423). Optional steps, which may be performed according to some specific embodiments, may be the forming of a protection layer on electrical connections, the forming of an additional gel protection layer for providing an additional chemical and or particle protection.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A transducer arrangement comprising:
a supporting structure;
a transducer die arranged on the supporting structure;
a lid comprising a porous material connected to the supporting structure and arranged to at least partially cover the transducer die.

2. The transducer arrangement according to claim 1, wherein the porous material is selected out of the group consisting of:
porous polyethylene;
porous polypropylene;
porous polytetrafluoroethylene;
porous polyvinylidene fluoride;
porous ethyl-vinyl acetate;
porous polycarbonate;
porous polyamide;
porous thermoplastic polyester polyurethane;
porous polyethersulfone; and
porous metal.

3. The transducer arrangement according to claim 1, wherein the porous material is a material with a porosity of at least 0.05.

4. The transducer arrangement according to claim 1, wherein the supporting structure is a structure selected out of the group consisting of:
a molded structure;
a lead frame;
a printed circuit board;
a multilayer structure;
a ceramic structure;
a laminated structure; and
a substrate.

5. The transducer arrangement according to claim 1,
wherein the supporting structure comprises an open cavity structure and wherein the transducer die is arranged in the open cavity structure.

6. The transducer arrangement according to claim 1,
wherein the transducer die forms one transducer out of the group consisting of:
a pressure sensor;
a chemical sensor;
a microphone;
a loudspeaker; and
a gas sensor.

7. The transducer arrangement according to claim 1, wherein the porous lid comprises a solid edge portion.

8. The transducer arrangement according to claim 1, wherein the transducer die comprises contact pads adapted to provide an electrical contact between the transducer die and an environment external to the transducer arrangement.

9. The transducer arrangement according to claim 8, wherein the contact pads comprise non-corrosive electrically conductive material.

10. The transducer arrangement according to claim 8, wherein the contact pads are covered by a protection layer.

11. The transducer arrangement according to claim 1, wherein the porous lid is attached to the supporting structure by at least one process out of the group consisting of:
glueing;
sintering;
molding;
soldering; and
welding.

12. The transducer arrangement according to claim 1, wherein the transducer die is partially covered by a mold compound.

13. The transducer arrangement according to claim 1, wherein the mold compound comprises a seat adapted to accommodate the lid.

14. The transducer arrangement according to claim 1, wherein a gel compound is arranged on the transducer die.

15. A method of covering a transducer die of a transducer arrangement, the method comprising:
providing a supporting structure;
arranging the transducer die on the supporting structure;
at least partially covering the arranged transducer die by placing a lid comprising a porous material on the supporting structure.

16. A transducer arrangement comprising:
a supporting structure;
a transducer die arranged on the supporting structure;
a lid comprising a material which comprises a plurality of through holes, wherein the lid is connected to the supporting structure and arranged to at least partially cover the transducer die.

17. The transducer arrangement according to claim 16, wherein a number of through holes is at least three.
